(19) United States
(12) Patent Application Publication
(10) Pub. No.: US 2026/0093187 A1
(43) Pub. Date: Apr. 2, 2026

(54) ELECTROSTATIC CLAMP WITH A STRUCTURED ELECTRODE BY POST BOND STRUCTURING

(71) Applicant: ASML Netherlands B.V., Veldhoven (NL)

(72) Inventors: Gustaaf Galein VAN EDEN, Utrecht (NL); Jeroen Arnoldus Leonardus Johannes RAAYMAKERS, Oirschot (NL); Tammo UITTERDIJK, Wilton, CT (US)

(73) Assignee: ASML Netherlands B.V., Veldhoven (NL)

(21) Appl. No.: 19/112,731

(22) PCT Filed: Sep. 20, 2023
(86) PCT No.: PCT/EP2023/075913

§ 371 Date: Mar. 18, 2025

Related U.S. Application Data
(60) Provisional application No. 63/378,892, filed on Oct. 10, 2022.

(51) Int. Cl. G03F 7/00; H02N 13/00

(52) U.S. Cl. CPC G03F 7/70708; H02N 13/00

(57) ABSTRACT

Disclosed herein are embodiments that relate to an electrostatic wafer clamps and methods for forming and modifying electrode structures for electrostatic wafer clamps. Wafer clamps include electrode structures in a dielectric layer with a plurality of burls interconnected via grounding lines. By modifying the electrode structures near the grounding lines by post bond structuring or the like, the electric field can be reduced, resulting in lower cycle inducing charging.

### CROSS-REFERENCE TO RELATED APPLICATIONS

This application claims priority of U.S. application 63/378,892 which was filed on 10 Oct. 2022, and which is incorporated herein in its entirety by reference.

### TECHNICAL FIELD

The present disclosure relates to electrostatic wafer clamps and methods for forming and modifying electrode structures for electrostatic wafer clamps.

### BACKGROUND

A lithographic apparatus is a machine that applies a desired pattern onto a substrate, or wafer, usually onto a target portion of the wafer. A lithographic apparatus can be used, for example, in the manufacture of integrated circuits (ICs). In that instance, a patterning device, which is interchangeably referred to as a mask or a reticle, can be used to generate a circuit pattern to be formed on an individual layer of the IC being formed. This pattern can be transferred onto a target portion (e.g., including part of, one, or several dies) on a wafer (e.g., a silicon wafer). Transfer of the pattern is typically via imaging onto a layer of radiation-sensitive material (e.g., resist) provided on the wafer. In general, a single wafer will contain a network of adjacent target portions that are successively patterned. Traditional lithographic apparatuses include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the target portions parallel or anti-parallel (e.g., opposite) to this scanning direction. It is also possible to transfer the pattern from the patterning device to the wafer by imprinting the pattern onto the wafer.

As semiconductor manufacturing processes continue to advance, the dimensions of circuit elements have continually been reduced while the amount of functional elements, such as transistors, per device has been steadily increasing over decades, following a trend commonly referred to as Moore's law. To keep up with Moore's law the semiconductor industry is chasing technologies that enable to create increasingly smaller features. To project a pattern on a wafer a lithographic apparatus may use electromagnetic radiation. The wavelength of this radiation determines the minimum size of features which are patterned on the wafer. Typical wavelengths currently in use are: 365 nm (i-line), 248 nm, and 193 nm in deep ultra violet (DUV) radiation systems; and 13.5 nm in extreme ultraviolet (EUV) radiation systems. EUV radiation, for example, electromagnetic radiation having wavelengths of around 50 nanometers (nm) or less (also sometimes referred to as soft x-rays), and including light at a wavelength of about 13.5 nm, can be used in or with a lithographic apparatus to produce extremely small features in or on wafers, for example, silicon wafers. A lithographic apparatus that uses EUV radiation having a wavelength within a range of 4 nm to 20 nm, for example 6.7 nm or 13.5 nm, can be used to form smaller features on a wafer than a lithographic apparatus using radiation with a wavelength of 193 nm, for example.

Wafers (i.e., substrates) are typically held on a wafer table using a wafer clamp. The wafer clamp may be, for example, a vacuum clamp for use in DUV radiation systems or an electrostatic clamp for use in EUV radiation systems. It is desirable to dictate and maintain tribological properties (e.g., friction, hardness, wear, etc.) on a surface of the wafer table. The wafer table, or a wafer clamp attached thereto, typically has a surface level tolerance that can be difficult to meet because of precision requirements of lithographic and metrology processes. Wafers are relatively thin (e.g., <1.0 millimeter (mm) thick) compared to a width of its surface area (e.g., >100.0 mm wide), are particularly sensitive to unevenness of the wafer table. Because ultra-smooth surfaces in contact can become stuck together, problems persist when a wafer must be disengaged from the wafer table. To reduce the smoothness of the surface that interfaces with the wafer, the surface of the wafer table or wafer clamp may include burls formed by patterning and etching of a wafer, for example. However, the wafer may sag in areas located between burls due to a combination of forces applied to the wafer by the burls, electrostatic clamping, backfill gas pressure, wafer stiffness, and/or gravity. Accordingly, there is a need for improved wafer clamps.

### SUMMARY

Disclosed herein are various embodiments of electrostatic wafer clamps and methods for forming and modifying electrode structures for electrostatic wafer clamps.

Some embodiments are directed to a support structure for positioning an exchangeable object in a lithographic apparatus. In some embodiments, the support structure can form a clamp mechanism and comprise a plurality of burls extending from a top surface of the clamp mechanism, wherein the clamp mechanism comprises a dielectric layer. In some embodiments, a plurality of grounding lines can be coated on the top surface. In some embodiments, at least one of the plurality of grounding lines can be configured to interconnect at least one of the plurality of burls. In some embodiments, an electrode layer can be embedded in the dielectric layer beneath the top surface. In some embodiments, the electrode layer can comprise an insulating material in the electrode layer. In some embodiments, a portion of the insulating material can be shaped to correspond with an exterior profile of the plurality of grounding lines such that an interior profile of the insulating material can be aligned with the exterior profile of the plurality of grounding lines.

In some embodiments, the shaping a portion of the insulating material can reduce charge effect near the plurality of grounding lines.

In some embodiments, the shaping can be done by post bond structuring.

In some embodiments, the post bond structuring is performed using a laser beam.

In some embodiments, the plurality of burls can comprise a conductive coating.

In some embodiments, the plurality of grounding lines can be configured to couple the plurality of burls to a ground potential.

In some embodiments, the embedding the electrode layer can comprise embedding using a chromium layer.

In some embodiments, the electrode layer can be formed with a contact hole.

In some embodiments, the electrode layer can be patterned.

In some embodiments, the exchangeable object and the dielectric layer can be positioned about 10 micrometers apart.

In some embodiments, a vacuum can be formed between the exchangeable object and the dielectric layer.

Further features of the present disclosure, as well as the structure and operation of various embodiments, are described in detail below with reference to the accompanying drawings. It is noted that the present disclosure is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS

The accompanying drawings, which are incorporated herein and form part of the specification, illustrate the present disclosure and, together with the description, further serve to explain the principles of the present disclosure and to enable a person skilled in the relevant art(s) to make and use embodiments described herein.

FIG. 1A shows a schematic of a reflective lithographic apparatus, according to some embodiments.

FIG. 1B shows a schematic of a transmissive lithographic apparatus, according to some embodiments.

FIG. 2 shows a more detailed schematic of the reflective lithographic apparatus, according to some embodiments.

FIG. 3 shows a schematic of a lithographic cell, according to some embodiments.

FIGS. 4A and 4B show schematics of lithographic apparatuses, according to some embodiments.

FIG. 5 shows a cross section of an electrostatic wafer clamp at a top-side of the dielectric layer, according to some embodiments.

FIG. 6 shows a cross-section of an electrostatic wafer clamp, according to some embodiments.

FIG. 7 shows another cross-section of an electrostatic wafer clamp, according to some embodiments.

FIGS. 8A, 8B, and 8C show an overhead view of an electrode plane and a close up of the electrode plane and MH lines, respectively, according to some embodiments.

FIG. 9 depicts an electric field strength in the z direction of an electrostatic wafer clamp, according to some embodiments.

FIG. 10 is a flowchart illustrating a process for forming and modifying electrode structures for electrostatic wafer clamps, according to some embodiments.

The features of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

This specification discloses one or more embodiments that incorporate the features of the present disclosure. The disclosed embodiment(s) are provided as examples. The scope of the present disclosure is not limited to the disclosed embodiment(s). Claimed features are defined by the claims appended hereto.

The embodiment(s) described, and references in the specification to “one embodiment,” “an embodiment,” “an example embodiment,” etc., indicate that the embodiment(s) described can include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Spatially relative terms, such as “beneath,” “below,” “lower,” “above,” “on,” “upper” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein may likewise be interpreted accordingly.

The term “about” as used herein indicates the value of a given quantity that can vary based on a particular technology. Based on the particular technology, the term “about” can indicate a value of a given quantity that varies within, for example, 10-30% of the value (e.g., ±10%, ±20%, or ±30% of the value).

Embodiments of the disclosure can be implemented in hardware, firmware, software, or any combination thereof. Embodiments of the disclosure may also be implemented as instructions stored on a machine-readable medium, which can be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, and/or instructions can be described herein as performing certain actions. However, it should be appreciated that such descriptions are merely for convenience and that such actions in fact result from computing devices, processors, controllers, or other devices executing the firmware, software, routines, instructions, etc.

Before describing such embodiments in more detail, however, it is instructive to present an example environment in which embodiments of the present disclosure can be implemented.

Example lithographic systems will now be described.

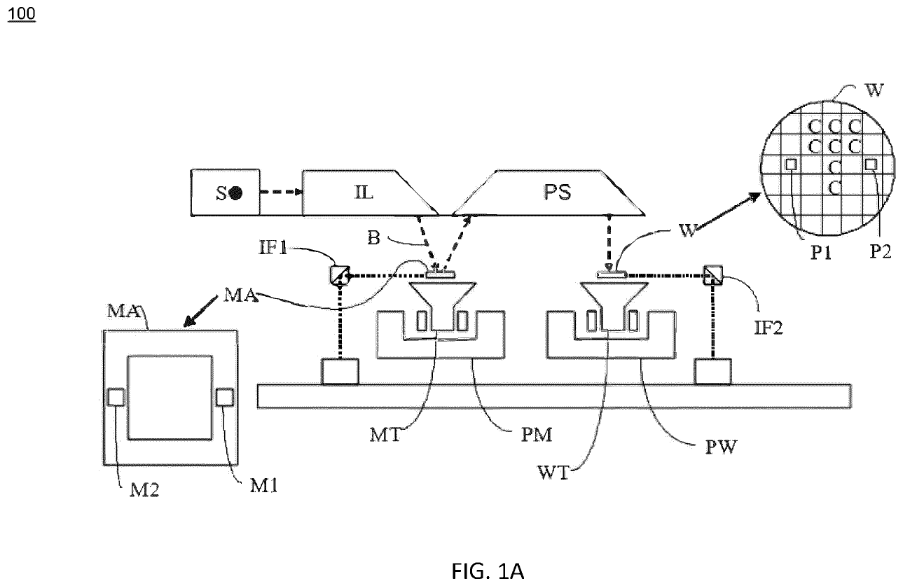

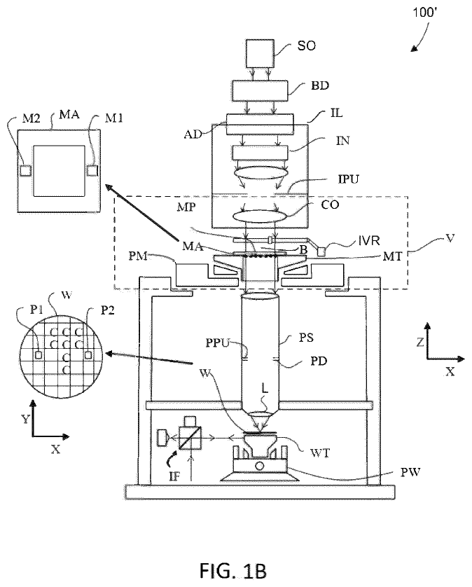

FIGS. 1A and 1B show schematic illustrations of a lithographic apparatus 100 and lithographic apparatus 100′, respectively, in which embodiments of the present disclosure can be implemented. Lithographic apparatus 100 and lithographic apparatus 100′ each include the following: an illumination system (illuminator) IL configured to condition a radiation beam B (for example, deep ultra violet or extreme ultra violet radiation); a support structure (for example, a mask table) MT configured to support a patterning device (for example, a mask, a reticle, or a dynamic patterning device) MA and connected to a first positioner PM configured to accurately position the patterning device MA; and, a wafer table (for example, a substrate table) WT configured to hold a wafer (for example, a resist coated wafer) W and connected to a second positioner PW configured to accurately position the wafer W. Lithographic apparatus 100 and 100′ also have a projection system PS configured to project a pattern imparted to the radiation beam B by patterning device MA onto a target portion (for example, comprising one or more dies) C of the wafer W. In lithographic apparatus 100, the patterning device MA and the projection system PS are reflective. In lithographic apparatus 100′, the patterning device MA and the projection system PS are transmissive.

The illumination system IL can include various types of optical components, such as refractive, reflective, catadioptric, magnetic, electromagnetic, electrostatic, or other types of optical components, or any combination thereof, for directing, shaping, or controlling the radiation beam B.

The support structure MT holds the patterning device MA in a manner that depends on the orientation of the patterning device MA with respect to a reference frame, the design of at least one of the lithographic apparatus 100 and 100′, and other conditions, such as whether or not the patterning device MA is held in a vacuum environment. The support structure MT can use mechanical, vacuum, electrostatic, or other clamping techniques to hold the patterning device MA. The support structure MT can be a frame or a table, for example, which can be fixed or movable, as required. By using sensors, the support structure MT can ensure that the patterning device MA is at a desired position, for example, with respect to the projection system PS.

The term “patterning device” MA should be broadly interpreted as referring to any device that can be used to impart a radiation beam B with a pattern in its cross-section, such as to create a pattern in the target portion C of the wafer W. The pattern imparted to the radiation beam B can correspond to a particular functional layer in a device being created in the target portion C to form an integrated circuit.

The terms “inspection apparatus,” “metrology system,” or the like can be used herein to refer to, e.g., a device or system used for measuring a property of a structure (e.g., overlay error, critical dimension parameters) or used in a lithographic apparatus to inspect an alignment of a wafer (e.g., alignment apparatus).

The patterning device MA can be transmissive (as in lithographic apparatus 100′ of FIG. 1B) or reflective (as in lithographic apparatus 100 of FIG. 1A). Examples of patterning devices MA include reticles, masks, programmable mirror arrays, or programmable LCD panels. Masks are well known in lithography, and include mask types such as binary, alternating phase shift, or attenuated phase shift, as well as various hybrid mask types. An example of a programmable mirror array employs a matrix arrangement of small mirrors, each of which can be individually tilted so as to reflect an incoming radiation beam in different directions. The tilted mirrors impart a pattern in the radiation beam B, which is reflected by a matrix of small mirrors.

The term “projection system” PScan encompass any type of projection system, including refractive, reflective, catadioptric, magnetic, electromagnetic and electrostatic optical systems, or any combination thereof, as appropriate for the exposure radiation being used, or for other factors, such as the use of an immersion liquid on the wafer W or the use of a vacuum. A vacuum environment can be used for EUV or electron beam radiation since other gases can absorb too much radiation or electrons. A vacuum environment can therefore be provided to the whole beam path with the aid of a vacuum wall and vacuum pumps.

Lithographic apparatus 100 and/or lithographic apparatus 100′ can be of a type having two (dual stage) or more wafer tables WT (and/or two or more mask tables). In such “multiple stage” machines, the additional wafer tables WT can be used in parallel, or preparatory steps can be carried out on one or more tables while one or more other wafer tables WT are being used for exposure. In some situations, the additional table may not be a wafer table WT.

The lithographic apparatus can also be of a type wherein at least a portion of the wafer can be covered by a liquid having a relatively high refractive index, e.g., water, so as to fill a space between the projection system and the wafer. An immersion liquid can be applied to other spaces in the lithographic apparatus, for example, between the mask and the projection system. Immersion techniques are well known in the art for increasing the numerical aperture of projection systems. The term “immersion” as used herein does not mean that a structure, such as a wafer, must be submerged in liquid, but rather only means that liquid is located between the projection system and the wafer during exposure.

Referring to FIGS. 1A and 1B, the illuminator IL receives a radiation beam from a radiation source SO. The source SO and the lithographic apparatus 100, 100′ can be separate physical entities, for example, when the source SO is an excimer laser. In such cases, the source SO is not considered to form part of the lithographic apparatus 100 or 100′, and the radiation beam B passes from the source SO to the illuminator IL with the aid of a beam delivery system BD (in FIG. 1B) including, for example, suitable directing mirrors and/or a beam expander. In other cases, the source SO can be an integral part of the lithographic apparatus 100, 100′, for example, when the source SO is a mercury lamp. The source SO and the illuminator IL, together with the beam delivery system BD, if required, can be referred to as a radiation system.

The illuminator IL can include an adjuster AD (in FIG. 1B) for adjusting the angular intensity distribution of the radiation beam. Generally, at least the outer and/or inner radial extent (commonly referred to as “σ-outer” and “σ-inner,” respectively) of the intensity distribution in a pupil plane of the illuminator can be adjusted. In addition, the illuminator IL can comprise various other components (in FIG. 1B), such as an integrator IN and a condenser CO. The illuminator IL can be used to condition the radiation beam B to have a desired uniformity and intensity distribution in its cross section.

Referring to FIG. 1A, the radiation beam B is incident on the patterning device (for example, mask) MA, which is held on the support structure (for example, mask table) MT, and is patterned by the patterning device MA. In lithographic apparatus 100, the radiation beam B is reflected from the patterning device (for example, mask) MA. After being reflected from the patterning device (for example, mask) MA, the radiation beam B passes through the projection system PS, which focuses the radiation beam B onto a target portion C of the wafer W. With the aid of the second positioner PW and position sensor IF2 (for example, an interferometric device, linear encoder, or capacitive sensor), the wafer table WT can be moved accurately (for example, so as to position different target portions C in the path of the radiation beam B). Similarly, the first positioner PM and another position sensor IF1 can be used to accurately position the patterning device (for example, mask) MA with respect to the path of the radiation beam B. Patterning device (for example, mask) MA and wafer W can be aligned using mask alignment marks M1, M2 and wafer alignment marks P1, P2.

Referring to FIG. 1B, the radiation beam B is incident on the patterning device (for example, mask MA), which is held on the support structure (for example, mask table MT), and is patterned by the patterning device. Having traversed the mask MA, the radiation beam B passes through the projection system PS, which focuses the beam onto a target portion C of the wafer W. The projection system has a pupil conjugate PPU to an illumination system pupil IPU. Portions of radiation emanate from the intensity distribution at the illumination system pupil IPU and traverse a mask pattern without being affected by diffraction at the mask pattern and create an image of the intensity distribution at the illumination system pupil IPU.

The projection system PS projects an image of the mask pattern MP, where the image is formed by diffracted beams produced from the mark pattern MP by radiation from the intensity distribution, onto a photoresist layer coated on the wafer W. For example, the mask pattern MP can include an array of lines and spaces. A diffraction of radiation at the array and different from zeroth order diffraction generates diverted diffracted beams with a change of direction in a direction perpendicular to the lines. Undiffracted beams (i.e., so-called zeroth order diffracted beams) traverse the pattern without any change in propagation direction. The zeroth order diffracted beams traverse an upper lens or upper lens group of the projection system PS, upstream of the pupil conjugate PPU of the projection system PS, to reach the pupil conjugate PPU. The portion of the intensity distribution in the plane of the pupil conjugate PPU and associated with the zeroth order diffracted beams is an image of the intensity distribution in the illumination system pupil IPU of the illumination system IL. The aperture device PD, for example, is disposed at or substantially at a plane that includes the pupil conjugate PPU of the projection system PS.

The projection system PS is arranged to capture, by means of a lens or lens group L, not only the zeroth order diffracted beams, but also first-order or first- and higher-order diffracted beams (not shown). In some embodiments, dipole illumination for imaging line patterns extending in a direction perpendicular to a line can be used to utilize the resolution enhancement effect of dipole illumination. For example, first-order diffracted beams interfere with corresponding zeroth-order diffracted beams at the level of the wafer W to create an image of the line pattern MP at highest possible resolution and process window (i.e., usable depth of focus in combination with tolerable exposure dose deviations). In some embodiments, astigmatism aberration can be reduced by providing radiation poles (not shown) in opposite quadrants of the illumination system pupil IPU. Further, in some embodiments, astigmatism aberration can be reduced by blocking the zeroth order beams in the pupil conjugate PPU of the projection system associated with radiation poles in opposite quadrants. This is described in more detail in U.S. Pat. No. 7,511,799 B2, issued Mar. 31, 2009, which is incorporated by reference herein in its entirety.

With the aid of the second positioner PW and position sensor IFD (for example, an interferometric device, linear encoder, or capacitive sensor), the wafer table WT can be moved accurately (for example, so as to position different target portions C in the path of the radiation beam B). Similarly, the first positioner PM and another position sensor (not shown in FIG. 1B) can be used to accurately position the mask MA with respect to the path of the radiation beam B (for example, after mechanical retrieval from a mask library or during a scan).

In general, movement of the mask table MT can be realized with the aid of a long-stroke module (coarse positioning) and a short-stroke module (fine positioning), which form part of the first positioner PM. Similarly, movement of the wafer table WT can be realized using a long-stroke module and a short-stroke module, which form part of the second positioner PW. In the case of a stepper (as opposed to a scanner), the mask table MT can be connected to a short-stroke actuator only or can be fixed. Mask MA and wafer W can be aligned using mask alignment marks M1, M2, and wafer alignment marks P1, P2. Although the wafer alignment marks (as illustrated) occupy dedicated target portions, they can be located in spaces between target portions (known as scribe-lane alignment marks). Similarly, in situations in which more than one die is provided on the mask MA, the mask alignment marks can be located between the dies.

Mask table MT and patterning device MA can be in a vacuum chamber V, where an in-vacuum robot IVR can be used to move patterning devices such as a mask in and out of vacuum chamber. Alternatively, when mask table MT and patterning device MA are outside of the vacuum chamber, an out-of-vacuum robot can be used for various transportation operations, similar to the in-vacuum robot IVR. Both the in-vacuum and out-of-vacuum robots need to be calibrated for a smooth transfer of any payload (e.g., mask) to a fixed kinematic mount of a transfer station.

The lithographic apparatus 100 and 100′ can be used in at least one of the following modes:
1. In step mode, the support structure (for example, mask table) MT and the wafer table WT are kept essentially stationary, while an entire pattern imparted to the radiation beam B is projected onto a target portion C at one time (i.e., a single static exposure). The wafer table WT is then shifted in the X and/or Y direction so that a different target portion C can be exposed.
2. In scan mode, the support structure (for example, mask table) MT and the wafer table WT are scanned synchronously while a pattern imparted to the radiation beam B is projected onto a target portion C (i.e., a single dynamic exposure). The velocity and direction of the wafer table WT relative to the support structure (for example, mask table) MT can be determined by the (de-) magnification and image reversal characteristics of the projection system PS.
3. In another mode, the support structure (for example, mask table) MT is kept substantially stationary holding a programmable patterning device, and the wafer table WT is moved or scanned while a pattern imparted to the radiation beam B is projected onto a target portion C. A pulsed radiation source SO can be employed and the programmable patterning device is updated as required after each movement of the wafer table WT or in between successive radiation pulses during a scan. This mode of operation can be readily applied to maskless lithography that utilizes a programmable patterning device, such as a programmable mirror array.

Combinations and/or variations on the described modes of use or entirely different modes of use can also be employed.

In a further embodiment, lithographic apparatus 100 includes an extreme ultraviolet (EUV) source, which is configured to generate a beam of EUV radiation for EUV lithography. In general, the EUV source is configured in a radiation system, and a corresponding illumination system is configured to condition the EUV radiation beam of the EUV source.

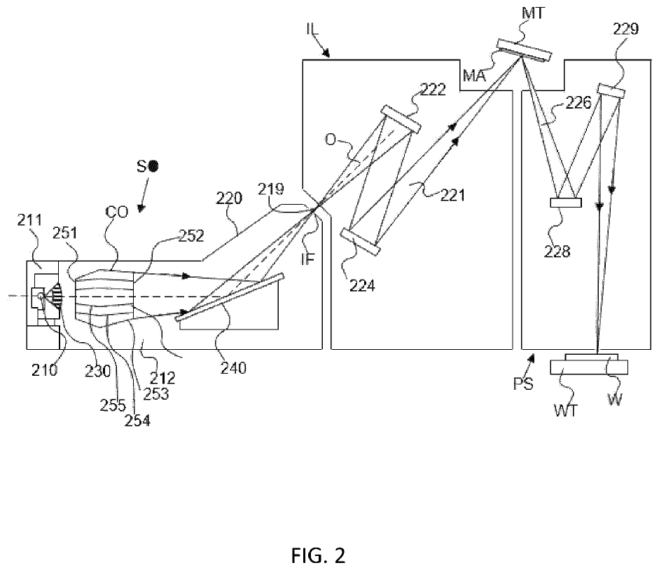

FIG. 2 shows the lithographic apparatus 100 in more detail, including the source collector apparatus SO, the illumination system IL, and the projection system PS. The source collector apparatus SO is constructed and arranged such that a vacuum environment can be maintained in an enclosing structure 220 of the source collector apparatus SO. An EUV radiation emitting plasma 210 can be formed by a discharge produced plasma source. EUV radiation can be produced by a gas or vapor, for example Xe gas, Li vapor, or Sn vapor in which the very hot plasma 210 is created to emit radiation in the EUV range of the electromagnetic spectrum. The very hot plasma 210 is created by, for example, an electrical discharge causing at least a partially ionized plasma. Partial pressures of, for example, 10 Pa of Xe, Li, Sn vapor, or any other suitable gas or vapor can be required for efficient generation of the radiation. In some embodiments, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap), which is positioned in or behind an opening in source chamber 211. The contaminant trap 230 can include a channel structure. Contamination trap 230 can also include a gas barrier or a combination of a gas barrier and a channel structure. The contaminant trap or contaminant barrier 230 further indicated herein at least includes a channel structure.

The collector chamber 212 can include a radiation collector CO, which can be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point INTF. The virtual source point INTF is commonly referred to as the intermediate focus, and the source collector apparatus is arranged such that the intermediate focus INTF is located at or near an opening 219 in the enclosing structure 220. The virtual source point INTF is an image of the radiation emitting plasma 210. Grating spectral filter 240 is used in particular for suppressing infra-red (IR) radiation.

Subsequently the radiation traverses the illumination system IL, which can include a faceted field mirror device 222 and a faceted pupil mirror device 224 arranged to provide a desired angular distribution of the radiation beam 221, at the patterning device MA, as well as a desired uniformity of radiation intensity at the patterning device MA. Upon reflection of the beam of radiation 221 at the patterning device MA, held by the support structure MT, a patterned beam 226 is formed and the patterned beam 226 is imaged by the projection system PS via reflective elements 228, 229 onto a wafer W held by the wafer stage or wafer table WT.

More elements than shown can generally be present in illumination optics unit IL and projection system PS. The grating spectral filter 240 can optionally be present, depending upon the type of lithographic apparatus. Further, there can be more mirrors present than those shown in the FIG. 2, for example there can be one to six additional reflective elements present in the projection system PS than shown in FIG. 2.

Collector optic CO, as illustrated in FIG. 2, is depicted as a nested collector with grazing incidence reflectors 253, 254, and 255, just as an example of a collector (or collector mirror). The grazing incidence reflectors 253, 254, and 255 are disposed axially symmetric around an optical axis O and a collector optic CO of this type is preferably used in combination with a discharge produced plasma source, often called a DPP source.

An exemplary lithographic cell will now be described.

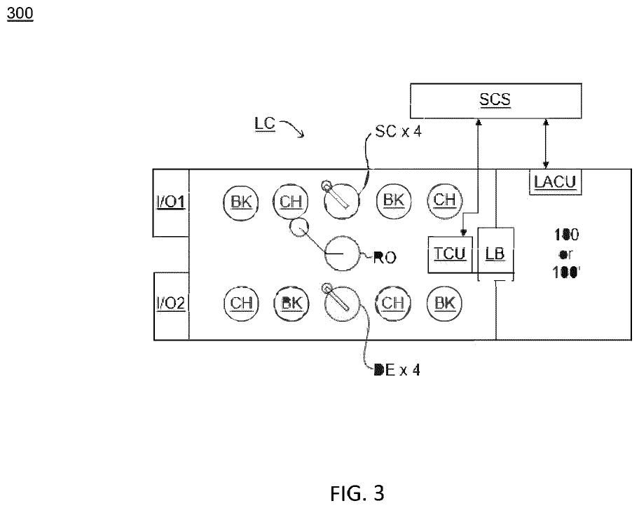

FIG. 3 shows a lithographic cell 300, also sometimes referred to a lithocell or cluster, according to some embodiments. Lithographic apparatus 100 or 100′ can form part of lithographic cell 300. Lithographic cell 300 can also include one or more apparatuses to perform pre- and post-exposure processes on a wafer. In some examples, these include spin coaters SC to deposit resist layers, developers DE to develop exposed resist, chill plates CH, and bake plates BK. A wafer handler, or robot, RO picks up wafers from input/output ports I/O1, I/O2, moves them between the different process apparatuses and delivers them to the loading bay LB of the lithographic apparatus 100 or 100′. These devices, which are often collectively referred to as the track, are under the control of a track control unit TCU, which is itself controlled by a supervisory control system SCS, which also controls the lithographic apparatus via lithography control unit LACU. Thus, the different apparatuses can be operated to maximize throughput and processing efficiency.

An exemplary inspection apparatus will now be described.

In order to control the lithographic process to place device features accurately on the wafer, alignment marks are generally provided on the wafer, and the lithographic apparatus includes one or more inspection apparatuses for accurate positioning of marks on a wafer. These alignment apparatuses are effectively position measuring apparatuses. Different types of marks and different types of alignment apparatuses and/or systems are known from different times and different manufacturers. A type of system widely used in current lithographic apparatus is based on a self-referencing interferometer as described in U.S. Pat. No. 6,961,116 (den Boef et al.). Generally marks are measured separately to obtain X- and Y-positions. A combined X- and Y-measurement can be performed using the techniques described in U.S. Publication No. 2009/195768 A (Bijnen et al.), however. The full contents of both of these disclosures are incorporated herein by reference.

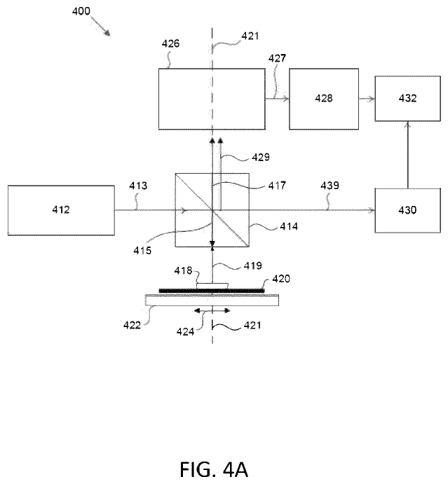

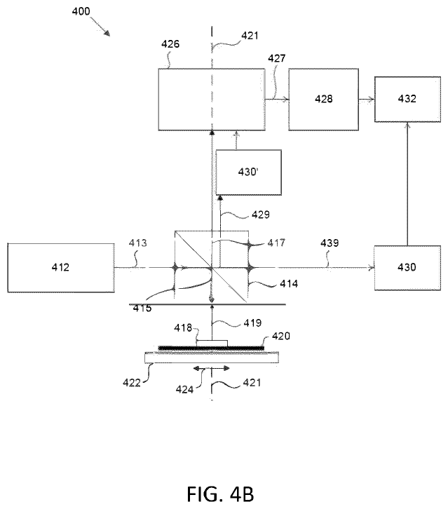

FIG. 4A shows a schematic of a cross-sectional view of an inspection apparatus 400 that can be implemented as a part of lithographic apparatus 100 or 100′, according to some embodiments. In some embodiments, inspection apparatus 400 can be configured to align a wafer (e.g., wafer W) with respect to a patterning device (e.g., patterning device MA). Inspection apparatus 400 can be further configured to detect positions of alignment marks on the wafer and to align the wafer with respect to the patterning device or other components of lithographic apparatus 100 or 100′ using the detected positions of the alignment marks. Such alignment of the wafer can ensure accurate exposure of one or more patterns on the wafer.

In some embodiments, inspection apparatus 400 can include an illumination system 412, a beam splitter 414, an interferometer 426, a detector 428, a beam analyzer 430, and an overlay calculation processor 432. Illumination system 412 can be configured to provide an electromagnetic narrow band radiation beam 413 having one or more passbands. In an example, the one or more passbands can be within a spectrum of wavelengths between about 500 nm to about 900 nm. In another example, the one or more passbands can be discrete narrow passbands within a spectrum of wavelengths between about 500 nm to about 900 nm. Illumination system 412 can be further configured to provide one or more passbands having substantially constant center wavelength (CWL) values over a long period of time (e.g., over a lifetime of illumination system 412). Such configuration of illumination system 412 can help to prevent the shift of the actual CWL values from the desired CWL values, as discussed above, in current alignment systems. And, as a result, the use of constant CWL values can improve long-term stability and accuracy of alignment systems (e.g., inspection apparatus 400) compared to the current alignment apparatuses.

In some embodiments, beam splitter 414 can be configured to receive radiation beam 413 and split radiation beam 413 into at least two radiation sub-beams. For example, radiation beam 413 can be split into radiation sub-beams 415 and 417, as shown in FIG. 4A. Beam splitter 414 can be further configured to direct radiation sub-beam 415 onto a wafer 420 placed on a stage 422. In one example, the stage 422 is movable along direction 424. Radiation sub-beam 415 can be configured to illuminate an alignment mark or a target 418 located on wafer 420. Alignment mark or target 418 can be coated with a radiation sensitive film. In some embodiments, alignment mark or target 418 can have one hundred and eighty degrees (i.e.,) 180° symmetry. That is, when alignment mark or target 418 is rotated 180° about an axis of symmetry perpendicular to a plane of alignment mark or target 418, rotated alignment mark or target 418 can be substantially identical to an unrotated alignment mark or target 418. The target 418 on wafer 420 can be (a) a resist layer grating comprising bars that are formed of solid resist lines, or (b) a product layer grating, or (c) a composite grating stack in an overlay target structure comprising a resist grating overlaid or interleaved on a product layer grating. The bars can alternatively be etched into the wafer. This pattern is sensitive to chromatic aberrations in the lithographic projection apparatus, particularly the projection system PL, and illumination symmetry and the presence of such aberrations will manifest themselves in a variation in the printed grating. One in-line method used in device manufacturing for measurements of line width, pitch, and critical dimension makes use of a technique known as “scatterometry”. Methods of scatterometry are described in Raymond et al., “Multiparameter Grating Metrology Using Optical Scatterometry”, J. Vac. Sci. Tech. B, Vol. 15, no. 2, pp. 361-368 (1997) and Niu et al., “Specular Spectroscopic Scatterometry in DUV Lithography”, SPIE, Vol. 3677 (1999), which are both incorporated by reference herein in their entireties. In scatterometry, light is reflected by periodic structures in the target, and the resulting reflection spectrum at a given angle is detected. The structure giving rise to the reflection spectrum is reconstructed, e.g. using Rigorous Coupled-Wave Analysis (RCWA) or by comparison to a library of patterns derived by simulation. Accordingly, the scatterometry data of the printed gratings is used to reconstruct the gratings. The parameters of the grating, such as line widths and shapes, can be input to the reconstruction process, performed by processing unit PU, from knowledge of the printing step and/or other scatterometry processes.

In some embodiments, beam splitter 414 can be further configured to receive diffraction radiation beam 419 and split diffraction radiation beam 419 into at least two radiation sub-beams, according to an embodiment. Diffraction radiation beam 419 can be split into diffraction radiation sub-beams 429 and 439, as shown in FIG. 4A.

It should be noted that even though beam splitter 414 is shown to direct radiation sub-beam 415 towards alignment mark or target 418 and to direct diffracted radiation sub-beam 429 towards interferometer 426, the disclosure is not so limiting. It would be apparent to a person skilled in the relevant art that other optical arrangements can be used to obtain the similar result of illuminating alignment mark or target 418 on wafer 420 and detecting an image of alignment mark or target 418.

As illustrated in FIG. 4A, interferometer 426 can be configured to receive radiation sub-beam 417 and diffracted radiation sub-beam 429 through beam splitter 414. In an example embodiment, diffracted radiation sub-beam 429 can be at least a portion of radiation sub-beam 415 that can be reflected from alignment mark or target 418. In an example of this embodiment, interferometer 426 comprises any appropriate set of optical-elements, for example, a combination of prisms that can be configured to form two images of alignment mark or target 418 based on the received diffracted radiation sub-beam 429. It should be appreciated that a good quality image need not be formed, but that the features of alignment mark 418 should be resolved. Interferometer 426 can be further configured to rotate one of the two images with respect to the other of the two images 180° and recombine the rotated and unrotated images interferometrically.

In some embodiments, detector 428 can be configured to receive the recombined image via interferometer signal 427 and detect interference as a result of the recombined image when alignment axis 421 of inspection apparatus 400 passes through a center of symmetry (not shown) of alignment mark or target 418. Such interference can be due to alignment mark or target 418 being 180° symmetrical, and the recombined image interfering constructively or destructively, according to an example embodiment. Based on the detected interference, detector 428 can be further configured to determine a position of the center of symmetry of alignment mark or target 418 and consequently, detect a position of wafer 420. According to an example, alignment axis 421 can be aligned with an optical beam perpendicular to wafer 420 and passing through a center of image rotation interferometer 426. Detector 428 can be further configured to estimate the positions of alignment mark or target 418 by implementing sensor characteristics and interacting with wafer mark process variations.

In a further embodiment, detector 428 determines the position of the center of symmetry of alignment mark or target 418 by performing one or more of the following measurements:
1. measuring position variations for various wavelengths (position shift between colors);
2. measuring position variations for various orders (position shift between diffraction orders); and
3. measuring position variations for various polarizations (position shift between polarizations).

This data can, for example, be obtained with any type of alignment sensor, for example a SMASH (SMart Alignment Sensor Hybrid) sensor, as described in U.S. Pat. No. 6,961,116 that employs a self-referencing interferometer with a single detector and four different wavelengths, and extracts the alignment signal in software, or Athena (Advanced Technology using High order Enhancement of Alignment), as described in U.S. Pat. No. 6,297,876, which directs each of seven diffraction orders to a dedicated detector, which are both incorporated by reference herein in their entireties.

In some embodiments, beam analyzer 430 can be configured to receive and determine an optical state of diffracted radiation sub-beam 439. The optical state can be a measure of beam wavelength, polarization, or beam profile. Beam analyzer 430 can be further configured to determine a position of stage 422 and correlate the position of stage 422 with the position of the center of symmetry of alignment mark or target 418. As such, the position of alignment mark or target 418 and, consequently, the position of wafer 420 can be accurately known with reference to stage 422. Alternatively, beam analyzer 430 can be configured to determine a position of inspection apparatus 400 or any other reference element such that the center of symmetry of alignment mark or target 418 can be known with reference to inspection apparatus 400 or any other reference element. Beam analyzer 430 can be a point or an imaging polarimeter with some form of wavelength-band selectivity. In some embodiments, beam analyzer 430 can be directly integrated into inspection apparatus 400, or connected via fiber optics of several types: polarization preserving single mode, multimode, or imaging, according to other embodiments.

In some embodiments, beam analyzer 430 can be further configured to determine the overlay data between two patterns on wafer 420. One of these patterns can be a reference pattern on a reference layer. The other pattern can be an exposed pattern on an exposed layer. The reference layer can be an etched layer already present on wafer 420. The reference layer can be generated by a reference pattern exposed on the wafer by lithographic apparatus 100 and/or 100′. The exposed layer can be a resist layer exposed adjacent to the reference layer. The exposed layer can be generated by an exposure pattern exposed on wafer 420 by lithographic apparatus 100 or 100′. The exposed pattern on wafer 420 can correspond to a movement of wafer 420 by stage 422. In some embodiments, the measured overlay data can also indicate an offset between the reference pattern and the exposure pattern. The measured overlay data can be used as calibration data to calibrate the exposure pattern exposed by lithographic apparatus 100 or 100′, such that after the calibration, the offset between the exposed layer and the reference layer can be minimized.

In some embodiments, beam analyzer 430 can be further configured to determine a model of the product stack profile of wafer 420, and can be configured to measure overlay, critical dimension, and focus of target 418 in a single measurement. The product stack profile contains information on the stacked product such as alignment mark, target 418, or wafer 420, and can include mark process variation-induced optical signature metrology that is a function of illumination variation. The product stack profile can also include product grating profile, mark stack profile, and mark asymmetry information. An example of beam analyzer 430 is Yieldstar™, manufactured by ASML, Veldhoven, The Netherlands, as described in U.S. Pat. No. 8,706,442, which is incorporated by reference herein in its entirety. Beam analyzer 430 can be further configured to process information related to a particular property of an exposed pattern in that layer. For example, beam analyzer 430 can process an overlay parameter (an indication of the positioning accuracy of the layer with respect to a previous layer on the wafer or the positioning accuracy of the first layer with respective to marks on the wafer), a focus parameter, and/or a critical dimension parameter (e.g., line width and its variations) of the depicted image in the layer. Other parameters are image parameters relating to the quality of the depicted image of the exposed pattern.

In some embodiments, an array of detectors (not shown) can be connected to beam analyzer 430, and allows the possibility of accurate stack profile detection as discussed below. For example, detector 428 can be an array of detectors. For the detector array, a number of options are possible: a bundle of multimode fibers, discrete pin detectors per channel, or CCD or CMOS (linear) arrays. The use of a bundle of multimode fibers enables any dissipating elements to be remotely located for stability reasons. Discrete PIN detectors offer a large dynamic range but each need separate pre-amps. The number of elements is therefore limited. CCD linear arrays offer many elements that can be read-out at high speed and are especially of interest if phase-stepping detection is used.

In some embodiments, a second beam analyzer 430′ can be configured to receive and determine an optical state of diffracted radiation sub-beam 429, as shown in FIG. 4B. The optical state can be a measure of beam wavelength, polarization, or beam profile. Second beam analyzer 430′ can be identical to beam analyzer 430. Alternatively, second beam analyzer 430′ can be configured to perform at least all the functions of beam analyzer 430, such as determining a position of stage 422 and correlating the position of stage 422 with the position of the center of symmetry of alignment mark or target 418. As such, the position of alignment mark or target 418 and, consequently, the position of wafer 420, can be accurately known with reference to stage 422. Second beam analyzer 430′ can also be configured to determine a position of inspection apparatus 400, or any other reference element, such that the center of symmetry of alignment mark or target 418 can be known with reference to inspection apparatus 400, or any other reference element. Second beam analyzer 430′ can be further configured to determine the overlay data between two patterns and a model of the product stack profile of wafer 420. Second beam analyzer 430′ can also be configured to measure overlay, critical dimension, and focus of target 418 in a single measurement.

In some embodiments, second beam analyzer 430′ can be directly integrated into inspection apparatus 400, or it can be connected via fiber optics of several types: polarization preserving single mode, multimode, or imaging, according to other embodiments. Alternatively, second beam analyzer 430′ and beam analyzer 430 can be combined to form a single analyzer (not shown) configured to receive and determine the optical states of both diffracted radiation sub-beams 429 and 439.

In some embodiments, processor 432 receives information from detector 428 and beam analyzer 430. For example, processor 432 can be an overlay calculation processor. The information can comprise a model of the product stack profile constructed by beam analyzer 430. Alternatively, processor 432 can construct a model of the product mark profile using the received information about the product mark. In either case, processor 432 constructs a model of the stacked product and overlay mark profile using or incorporating a model of the product mark profile. The stack model is then used to determine the overlay offset and minimizes the spectral effect on the overlay offset measurement. Processor 432 can create a basic correction algorithm based on the information received from detector 428 and beam analyzer 430, including but not limited to the optical state of the illumination beam, the alignment signals, associated position estimates, and the optical state in the pupil, image, and additional planes. The pupil plane is the plane in which the radial position of radiation defines the angle of incidence and the angular position defines the azimuth angle of the radiation. Processor 432 can utilize the basic correction algorithm to characterize the inspection apparatus 400 with reference to wafer marks and/or alignment marks 418.

In some embodiments, processor 432 can be further configured to determine printed pattern position offset error with respect to the sensor estimate for each mark based on the information received from detector 428 and beam analyzer 430. The information includes but is not limited to the product stack profile, measurements of overlay, critical dimension, and focus of each alignment marks or target 418 on wafer 420. Processor 432 can utilize a clustering algorithm to group the marks into sets of similar constant offset error, and create an alignment error offset correction table based on the information. The clustering algorithm can be based on overlay measurement, the position estimates, and additional optical stack process information associated with each set of offset errors. The overlay is calculated for a number of different marks, for example, overlay targets having a positive and a negative bias around a programmed overlay offset. The target that measures the smallest overlay is taken as reference (as it is measured with the best accuracy). From this measured small overlay, and the known programmed overlay of its corresponding target, the overlay error can be deduced. Table 1 illustrates how this can be performed. The smallest measured overlay in the example shown is −1 nm. However this is in relation to a target with a programmed overlay of −30 nm. The process may have introduced an overlay error of 29 nm.

TABLE 1

| | | | | | | | |
|---|---|---|---|---|---|---|---|
| Programmed overlay | −70 | −50 | −30 | −10 | 10 | 30 | 50 |
| Measured overlay | −38 | −19 | −1 | 21 | 43 | 66 | 90 |
| Difference between | 32 | 31 | 29 | 31 | 33 | 36 | 40 |
| measured and | | | | | | | |
| programmed overlay | | | | | | | |
| Overlay error | 3 | 2 | — | 2 | 4 | 7 | 11 |

The smallest value can be taken to be the reference point and, relative to this, the offset can be calculated between measured overlay and that expected due to the programmed overlay. This offset determines the overlay error for each mark or the sets of marks with similar offsets. Therefore, in the Table 1 example, the smallest measured overlay was −1 nm, at the target position with programmed overlay of 30 nm. The difference between the expected and measured overlay at the other targets is compared to this reference. A table such as Table 1 can also be obtained from marks and target 418 under different illumination settings, the illumination setting, which results in the smallest overlay error, and its corresponding calibration factor, can be determined and selected. Following this, processor 432 can group marks into sets of similar overlay error. The criteria for grouping marks can be adjusted based on different process controls, for example, different error tolerances for different processes.

In some embodiments, processor 432 can confirm that all or most members of the group have similar offset errors, and apply an individual offset correction from the clustering algorithm to each mark, based on its additional optical stack metrology. Processor 432 can determine corrections for each mark and feed the corrections back to lithographic apparatus 100 or 100′ for correcting errors in the overlay, for example, by feeding corrections into the inspection apparatus 400.

Exemplary embodiments of electrostatic wafer clamps and methods for forming and modifying electrode structures included in electrostatic wafer clamps will now be described. The described embodiments and methods may also be applied to reticles (also referred to as patterning devices) and reticle clamps. Wafers, substrates, reticles, patterning devices, and any related structures may be referred to as objects, or exchangeable objects. These exemplary embodiments may be used in the lithographic apparatus' of FIGS. 1-4.

Most electrostatic wafer clamps in the lithographic apparatus include two continuous electrodes, which may be located (e.g., embedded) in a dielectric material. A plurality of burls can be disposed on top of the wafer clamp to support the wafer, and may be covered by a conducting coating as described in more detail below. The plurality of burls and a dielectric layer can form a clamp mechanism using the wafer clamp. The burls can also be interconnected by a series of Manhattan (MH) lines that can also be disposed on top of the wafer clamp. In some embodiments, the MH lines are not electrically or physically connected to the wafer or the burls. The main purpose for the MH lines herein is to ground the burls.

Electrostatic clamps work on the principle of parallel plate capacitance. The electrostatic clamp functions by generating a very high electric field in a vacuum gap. The vacuum gap is created between wafer and wafer clamp. The MH lines can be positioned in the electric field to ground the burls. The MH lines can be a source of electric field amplification at triple point corners, asperities, and/or debris particles. The term “triple point” refers to any location where a dielectric material and a metal abut in a vacuum.

The MH lines can be a source of electric field amplification because they may act as a cathode, leading to the emission of electrons, which is highly undesirable. Next to the MH lines, quasi-uniform charging of the dielectric surface can occur when cycling wafers on and off the wafer clamp/table. The quasi-uniform charging may be referred to as a cycle-induced charging (CIC) problem. Non-uniform charging can occur when debris particles become attached to the MH lines at critical positions. Critical positions can include the triple point, a top corner of the MH line, or at asperities along a side wall of the MH line, for example.

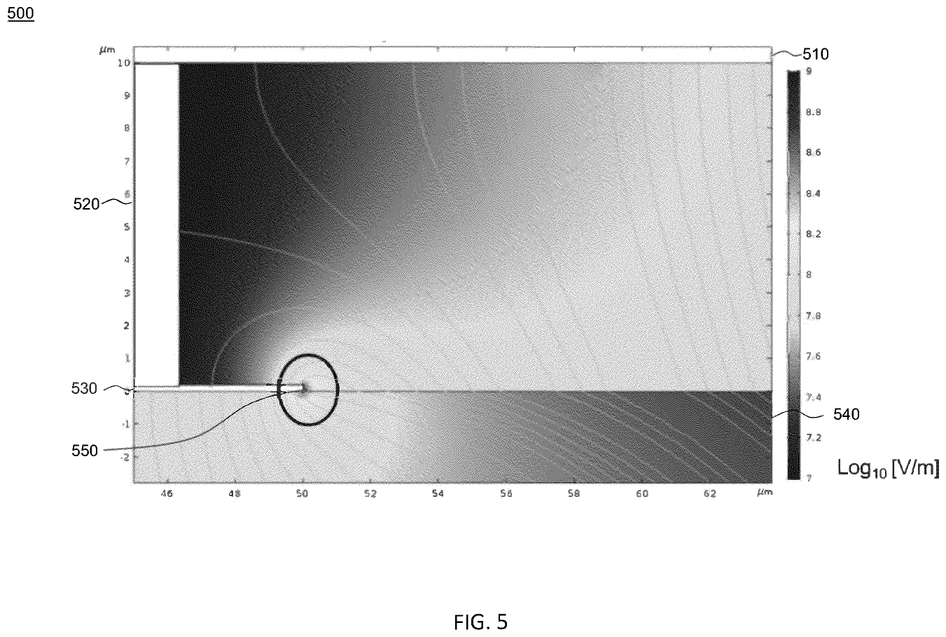

FIG. 5 shows a magnified cross section of an electrostatic wafer clamp 500 at a top-side of the dielectric layer 540, according to some embodiments. Although only one view is shown, the electrostatic wafer clamp 500 can comprise a plurality of layers. Specifically, a MH line 530 is disposed on (e.g., top of) a dielectric layer 540. The MH line 530 can contact a burl 520, but can also be interconnected with the burl 520. The MH line 530 can contact both the burl 520 and the dielectric layer 540. The burl 520 can be grounded using the MH line 530. The burl 520 and dielectric layer 540 can both be made of glass, for example. The burl 520 can be made of glass or a similar dielectric and the MH line 530 can be a conductor.

The burl 520 can further comprise a conductive coating (not pictured). The conductive layer can be formed between about 300 mm and about 1500 mm thick. A wafer 510 is on top of the clamp mechanism with the electrostatic wafer clamp 500 at vacuum pressure. A backfill gas can be applied after clamping the wafer 510. An adhesion (not pictured) can be disposed between any of the layers described herein so as to serve as an intermediate adhesive. Such an added adhesion layer can comprise benzocyclobutene (BCB), for example. The dielectric layer 540 can be made from glass, for example, Eagle XG® Borosilicate Glass, manufactured by Corning Incorporated, Corning New York.

An example triple point 550 is illustrated at a junction where the dielectric layer 540, MH line 530, and the vacuum (not illustrated) intersect. At the triple point 550, the electric field strength is more intense, as illustrated by the log scale of the electric field strength. The distance between the dielectric layer 540 and the bottom of the wafer 510 can be up to about 10 μm, but can be between about 6 and about 12 μm, for example.

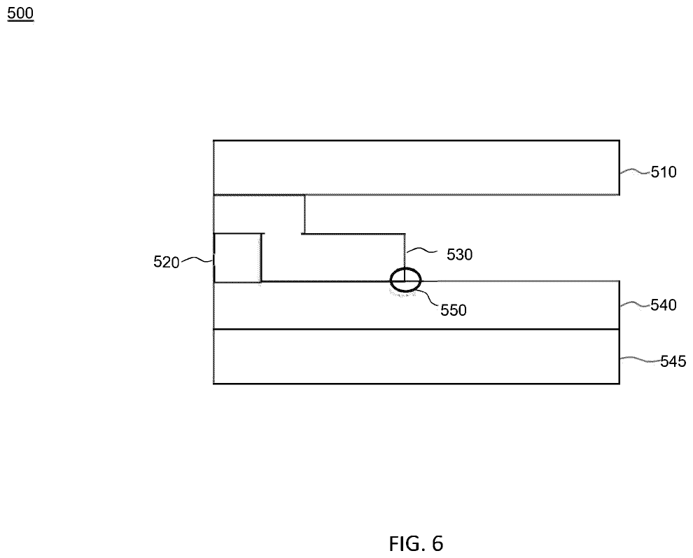

FIG. 6 shows a cross-section of an electrostatic wafer clamp 500, according to some embodiments. The dielectric layer 540 is shown with an embedded electrode 545. The embedded electrode 545 can be formed of chromium, for example.

In order to overcome the quasi-uniform charging, the electrode 545 embedded in the dielectric layer 540 is altered, according to some embodiments. While the MH line 530 can remain unaltered, a small fraction of the electrode 545 adjacent to MH line 530 can be converted into an insulating material using a post bond structuring (PBS) process. Additionally, removing a portion of the electrode 545 below the MH lines 530 is permissible. This removal can be performed using lithography, for example. Removal of the section need not be limited to only PBS, and other suitable processes can be utilized, such as patterning the electrode via lithography processing. The section removed can be a continuous strip along the MH lines 530, and can extend on both sides up to about 50 μm away from the MH lines 530. Such PBS processing, or the like, converts a section of the electrode 545 to an insulating material.

The section removed can be shaped to correspond to the shape of the MH lines 530 such that an insulating material aligns with the MH lines 530 above it. In an embodiment, not all of the electrode 545 is removed such that a portion of the electrode 545 remains. Shaping a portion of the insulating material can correspond with an exterior profile of the MH lines 530. By corresponding the interior profile of the insulating material with the exterior profile of the MH lines 530, charging issues can be reduced. For example, the charge effect near the MH lines 530 can may be reduced.

Altering of the electrode 545 results in a lowered electric field strength at the MH line 530 sidewalls on the entire clamp. This alteration reduces charging effects as a result of processing and defectivity on and near the MH lines 530. Additionally, a nominal clamping force in between the burls 520 need not change. The total clamping force may decrease by having a smaller effective electrode area underneath the wafer 510. In some embodiments, the area under the MH lines 530 does not contribute to the clamping force, but can be compensated by having a slightly higher clamping voltage, which is possible as charging issues are reduced herein. A clamping voltage of about 3.2 kV can be used, but can be varied depending on the clamping pressure.

In some embodiments, PBS of the electrode 545 can be done at several stages in the clamp manufacturing process, but may also be done on finished or used clamps. The MH lines 530 can serve as guides to maneuver the PBS laser beam, which may be applied through the transparent dielectric layer 540. This maneuver can allow for finished clamps to be refurbished. Additionally, the PBS can be performed at an angle, rather than perpendicular to the surface, to remove a portion of the electrode layer under the MH lines 530.

In some embodiments, the PBS process can melt and, or vaporize the portion of electrode 545 to be removed. The section around the removed area may be changed into an insulating material, also referred to as an insulator. In some embodiments, the thin conducting layer of the electrode is turned into an insulating layer.

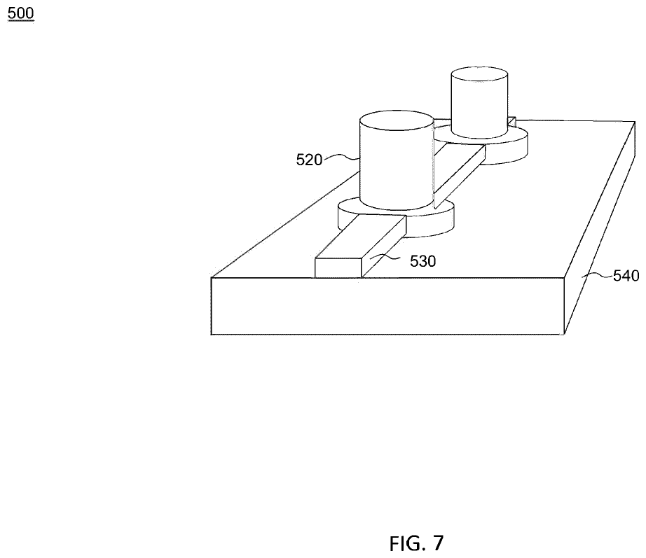

FIG. 7 shows another cross-section of an electrostatic wafer clamp 500, according to some embodiments. The dielectric layer 540 is shown with a MH line 530 and a burl 520.

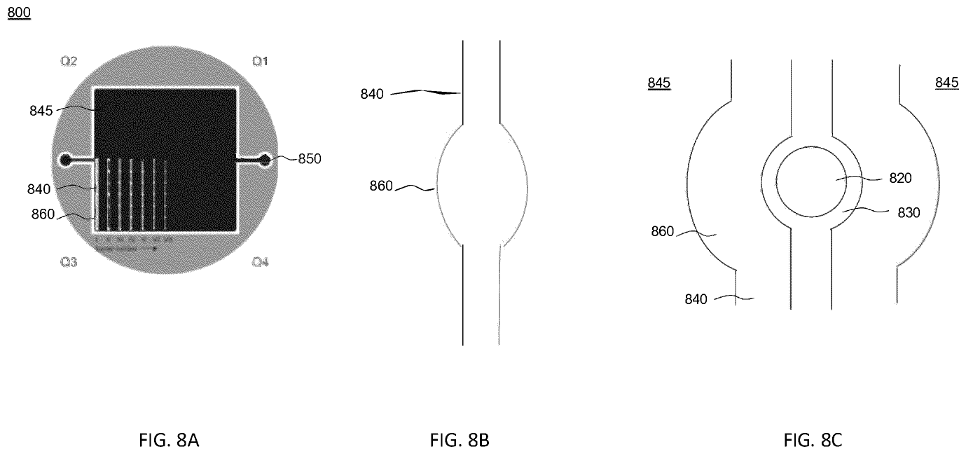

FIGS. 8A, 8B, and 8C show an overhead view of an electrode plane and a close up of the electrode plane and MH lines, respectively, according to some embodiments.

FIG. 8A shows an overhead electrode plane of a structured electrode 800. An electrode 845 is shown, with various electrode cutouts 840 and 860 of varying (or alternatively similar) sizes. The electrode cutouts 840 and 860 are removed underneath the MH line and result in a structured electrode. Here, the densities of the electrode cutouts 840 and 860 are illustrated as varying in width from left to right for testing purposes. In practice for an operational electrode, the density of the electrode cutouts 840 and 860 can be uniform. A contact hole 850 is shown and the electrode 845 is at the bottom of the hole. The contact hole 850 can connect the electrode 845 to an external power supply, for example.

FIG. 8B shows a close up of an electrode cutout 840 and electrode cutout 860 that are under a MH line and a burl (both not pictured here). The electrode cutout 860 can extend up to about 50 μm on each side, for example.

FIG. 8C shows a top view of both the electrode 845 and MH line 830. A MH line 830 can surround burl 820. The burl 820 may also be contacted or partially contacted by the MH line 830. The electrode cutout 840 shows an area of the removed electrode 845. The electrode cutout 860 shows an area of the removed electrode 845 in a circular manner.

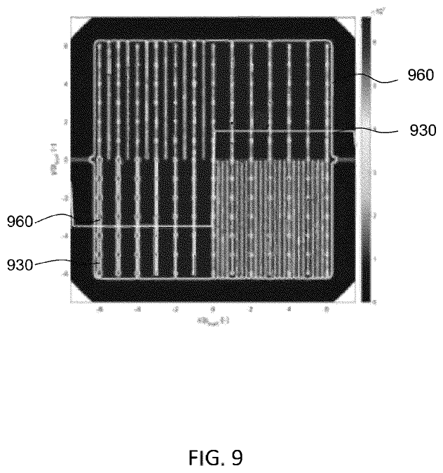

FIG. 9 depicts an electric field in the z direction of an electrostatic wafer clamp, according to some embodiments. The MH lines 930 extend in a vertical direction with the electrode cutout areas 960 along with MH lines 930. The electric field strength in the lower left quadrant is reduced in the area surrounding the MH lines 930. In this quadrant, the MH lines 930 are with structured electrodes of varying widths (not pictured). Here, structured electrode means that a part of the electrode has been removed and shaped, as described in connection with FIG. 6. The top right quadrant, however, does not have structured electrodes (not pictured) and does not have a reduced electric field strength along the MH lines 930. As the electric field strength is locally reduced, the field emission current density can also be reduced.

With a part of the electrode being cutout resulting in a structured electrode, a complete absence of cycle-induced charging (CIC) occurs in the cutout region. However, CIC is strongly observed in other sections where a standard electrode layout, i.e. no cutout, occurs. In the top right quadrant of FIG. 9, no structured electrode is used and significant charging near the MH lines occurs (not shown). The electric field strength is stronger here than in the lower left quadrant, alongside the MH lines.

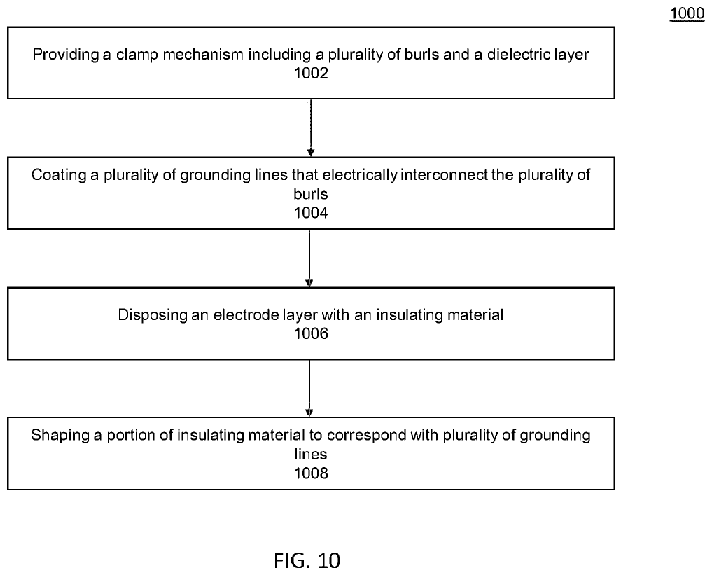

FIG. 10 is a flowchart illustrating a process 1000 for forming and modifying electrode structures for electrostatic wafer clamps. In step 1002, a clamp mechanism can be provided. Specifically, the clamp mechanism comprises a plurality of burls that can extend from a top surface of the clamp mechanism. The clamp mechanism can comprises a dielectric layer.

In step 1004, a plurality of grounding lines, also known as MH lines, can be coated on the top surface of the clamp mechanism. At least one of the plurality of grounding lines can interconnect at least one of the plurality of burls.

In step 1006, an electrode layer can be disposed in the dielectric layer beneath the top surface of the clamp mechanism. The electrode layer can comprise an insulating material in the electrode layer.

In step 1008, a portion of the insulating material can be shaped to correspond with an exterior profile of the plurality of grounding lines. The interior profile of the insulating material can be aligned with the exterior profile of the plurality of grounding lines.

A structured electrode below MH lines can avoid CIC and can reduce the risk of charging by defects located on or near the MH lines. Additionally, manufacturing costs can be lowered, as this technique of structured electrodes can be used on already existing clamps. Existing clamps can be refurbished using PBS to reduce surface charging issues. The clamps can be operated with a structured electrode at voltages greater than 3.2 kV. This achieves higher clamp forces without increased charging issues. Hence, the structured electrodes disclosed herein and formed by PBS, or the like processes, assists in reducing undesirable surface charging.

Although specific reference can be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, LCDs, thin-film magnetic heads, etc. The skilled artisan will appreciate that, in the context of such alternative applications, any use of the terms “wafer” or “die” herein can be considered as specific examples of the more general terms “substrate” or “target portion”, respectively. The wafer referred to herein can be processed, before or after exposure, in for example a track unit (a tool that typically applies a layer of resist to a wafer and develops the exposed resist) and/or a metrology unit. Where applicable, the disclosure herein can be applied to such and other wafer processing tools. Further, the wafer can be processed more than once, for example in order to create a multi-layer IC, so that the term wafer used herein may also refer to a wafer that already contains multiple processed layers.

Although specific reference may have been made above to the use of embodiments of the present disclosure in the context of optical lithography, it will be appreciated that the present disclosure can be used in other applications, for example imprint lithography, and where the context allows, is not limited to optical lithography. In imprint lithography a topography in a patterning device defines the pattern created on a wafer. The topography of the patterning device can be pressed into a layer of resist supplied to the wafer whereupon the resist is cured by applying electromagnetic radiation, heat, pressure or a combination thereof. The patterning device is moved out of the resist leaving a pattern in it after the resist is cured.

It is to be understood that the phraseology or terminology herein is for the purpose of description and not of limitation, such that the terminology or phraseology of the present disclosure is to be interpreted by those skilled in relevant art(s) in light of the teachings herein.

The terms “radiation,” “beam of radiation” or the like as used herein can encompass various types of electromagnetic radiation, for example, ultraviolet (UV) radiation (for example, having a wavelength λ of 365, 248, 193, 157 or 126 nm), extreme ultraviolet (EUV or soft X-ray) radiation (for example, having a wavelength in the range of 5-20 nm such as, for example, 13.5 nm), or hard X-ray working at less than 5 nm, as well as matter beams, such as ion beams or electron beams. The terms “light,” “illumination,” or the like can refer to non-matter radiation (e.g., photons, UV, X-ray, or the like). Generally, radiation having wavelengths between about 400 to about 700 nm is considered visible radiation; radiation having wavelengths between about 780-3000 nm (or larger) is considered IR radiation. UV refers to radiation with wavelengths of approximately 100-400 nm. Within lithography, the term “UV” also applies to the wavelengths that can be produced by a mercury discharge lamp: G-line 436 nm; H-line 405 nm; and/or, I-line 365 nm. Vacuum UV, or VUV (i.e., UV absorbed by gas), refers to radiation having a wavelength of approximately 100-200 nm. Deep UV (DUV) generally refers to radiation having wavelengths ranging from 126 nm to 428 nm, and in some embodiments, an excimer laser can generate DUV radiation used within a lithographic apparatus. It should be appreciated that radiation having a wavelength in the range of, for example, 5-20 nm relates to radiation with a certain wavelength band, of which at least part is in the range of 5-20 nm.

Aspects of the present disclosure can further be described using the following clauses:
1. A method of manufacturing a support structure for positioning an exchangeable object in a lithographic apparatus comprising:
   providing a clamp mechanism comprising a plurality of burls extending from a top surface of the clamp mechanism, wherein the clamp mechanism comprises a dielectric layer;
   coating a plurality of grounding lines on the top surface of the clamp mechanism, wherein the grounding lines are located to electrically interconnect the plurality of the burls;
   disposing an electrode layer in the dielectric layer beneath the top surface of the clamp mechanism, wherein the electrode layer comprises an insulating material in the electrode layer; and
   shaping a portion of the insulating material to correspond with an exterior profile of the plurality of grounding lines such that an interior profile of the insulating material is aligned with the exterior profile of the plurality of grounding lines.
2. The method according to clause 1, further comprising shaping a portion of the insulating material to reduce charge effect near the plurality of grounding lines.
3. The method of according to clause 1, wherein the shaping comprises post bond structuring.
4. The method of clause 3, wherein the post bond structuring comprises using a laser beam.
5. The method according to clause 1, further comprising disposing a conductive coating on the plurality of burls.
6. The method according to clause 1, further comprising coupling the plurality of grounding lines and the plurality of burls to a ground potential.
7. The method according to clause 1, wherein the disposing the electrode layer comprises embedding a chromium layer.
8. The method according to clause 1, further comprising forming the electrode layer with a contact hole.
9. The method according to clause 1, further comprising patterning the electrode layer.
10. The method according to clause 1, further comprising positioning the exchangeable object and the dielectric layer about 10 micrometers apart.
11. The method according to clause 10, further comprising forming a vacuum between the exchangeable object and the dielectric layer by the clamp mechanism.
12. A support structure for positioning an exchangeable object in a lithographic apparatus comprising:
   a clamp mechanism comprising a plurality of burls extending from a top surface of the clamp mechanism, wherein the clamp mechanism comprises a dielectric layer;
   a plurality of grounding lines located on the top surface, wherein the grounding lines electrically interconnect the plurality of the burls; and
   an electrode layer located in the dielectric layer beneath the top surface, wherein the electrode layer comprises an insulating material in the electrode layer,
   wherein the insulating material comprises an interior profile shaped to correspond with an exterior profile of the plurality of grounding lines such that the interior profile of the insulating material is aligned with the exterior profile of the plurality of grounding lines.
13. The support structure according to clause 12, wherein the exterior profile of the insulating material is configured to reduce charge effect near the plurality of grounding lines.
14. The support structure according to clause 12, wherein the plurality of burls comprises a conductive coating.
15. The support structure according to clause 12, wherein the plurality of grounding lines electrically couple the plurality of burls to a ground potential.
16. The support structure according to clause 12, wherein the electrode layer comprises chromium.
17. The support structure according to clause 12, wherein electrode layer comprises a contact hole.
18. The support structure according to clause 12, wherein the electrode layer is patterned.
19. The support structure according to clause 12, wherein the exchangeable object and the dielectric layer are separated by about 10 micrometers.
20. The support structure according to clause 19, wherein a vacuum is formed between the exchangeable object and the dielectric layer by the clamp mechanism.

It is to be appreciated that the Detailed Description section, and not the Summary and Abstract sections, is intended to be used to interpret the claims. The Summary and Abstract sections may set forth one or more but not all exemplary embodiments of the present disclosure as contemplated by the inventor(s), and thus, are not intended to limit the present disclosure and the appended claims in any way.

The present disclosure has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

While specific embodiments of the disclosure have been described above, it will be appreciated that embodiments of the present disclosure may be practiced otherwise than as described. The descriptions are intended to be illustrative, not limiting. Thus it will be apparent to one skilled in the art that modifications may be made to the disclosure as described without departing from the scope of the claims set out below.

The foregoing description of the specific embodiments will so fully reveal the general nature of the present disclosure that others can, by applying knowledge within the skill of the art, readily modify and/or adapt for various applications such specific embodiments, without undue experimentation, without departing from the general concept of the present disclosure. Therefore, such adaptations and modifications are intended to be within the meaning and range of equivalents of the disclosed embodiments, based on the teaching and guidance presented herein.

The breadth and scope of the protected subject matter should not be limited by any of the above-described exemplary embodiments, but should be defined only in accordance with the following claims and their equivalents.

1.-15. (canceled)

16. A method of manufacturing a support structure for positioning an exchangeable object in a lithographic apparatus comprising:
providing a clamp mechanism comprising a plurality of burls extending from a top surface of the clamp mechanism, wherein the clamp mechanism comprises a dielectric layer;
coating a plurality of grounding lines on the top surface of the clamp mechanism, wherein the grounding lines are located to electrically interconnect the plurality of the burls;
disposing an electrode layer in the dielectric layer beneath the top surface of the clamp mechanism, wherein the electrode layer comprises an insulating material in the electrode layer; and
shaping a portion of the insulating material to correspond with an exterior profile of the plurality of grounding lines such that an interior profile of the insulating material is aligned with the exterior profile of the plurality of grounding lines.

17. The method of claim 16, further comprising shaping a portion of the insulating material to reduce charge effect near the plurality of grounding lines.

18. The method of claim 16, wherein the shaping comprises post bond structuring, and wherein the post bond structuring comprises using a laser beam.

19. The method of claim 16, further comprising:
disposing a conductive coating on the plurality of burls; and
coupling the plurality of grounding lines and the plurality of burls to a ground potential.

20. The method of claim 16, wherein the disposing the electrode layer comprises embedding a chromium layer.

21. The method of claim 16, further comprising:
forming the electrode layer with a contact hole; and
patterning the electrode layer.

22. The method of claim 16, further comprising:
positioning the exchangeable object and the dielectric layer apart from one another; and
forming a vacuum between the exchangeable object and the dielectric layer by the clamp mechanism.

23. A support structure for positioning an exchangeable object in a lithographic apparatus comprising:
a clamp mechanism comprising a plurality of burls extending from a top surface of the clamp mechanism, wherein the clamp mechanism comprises a dielectric layer;
a plurality of grounding lines located on the top surface, wherein the grounding lines electrically interconnect the plurality of the burls; and
an electrode layer located in the dielectric layer beneath the top surface, wherein the electrode layer comprises an insulating material in the electrode layer,
wherein the insulating material comprises an interior profile shaped to correspond with an exterior profile of the plurality of grounding lines such that the interior profile of the insulating material is aligned with the exterior profile of the plurality of grounding lines.

24. The support structure of claim 23, wherein the exterior profile of the insulating material is configured to reduce charge effect near the plurality of grounding lines.

25. The support structure of claim 23, wherein the plurality of burls comprises a conductive coating.

26. The support structure of claim 23, wherein the plurality of grounding lines electrically couple the plurality of burls to a ground potential.

27. The support structure of claim 8, wherein the electrode layer comprises chromium.

28. The support structure of claim 8, wherein electrode layer comprises a contact hole.

29. The support structure of claim 8, wherein the electrode layer is patterned.

30. The support structure of claim 8, wherein the exchangeable object and the dielectric layer are separated by a gap, and wherein a vacuum is formed between the exchangeable object and the dielectric layer by the clamp mechanism.
